(19) United States
(12) Patent Application Publication
(10) Pub. No.: US 2005/0115946 A1
(43) Pub. Date: Jun. 2, 2005

(54) Radical assisted oxidation apparatus

(76) Inventors: Kyu Hwan Shim, Daejeon-Shi (KR); Young Joo Song, Daejeon-Shi (JP); Sang Hoon Kim, Daejeon-Shi (KR); Nae Eung Lee, Gwacheon-shi (KR); Jin Yeong Kang, Daejeon-Shi (KR)

Correspondence Address: JACOBSON HOLMAN PLLC, 400 SEVENTH STREET N.W., SUITE 600, WASHINGTON, DC, 20004, US

(21) Appl. No.: 10/817,851

(22) Filed: Apr. 6, 2004

(30) Foreign Application Priority Data
Dec. 2, 2003 (KR) 2003-86660

(51) Int. Cl. F27B 5/14; H01L 21/44

(52) U.S. Cl. 219/390

(57) ABSTRACT

Provided is a radical assisted oxidation apparatus comprising a gas supply system, a radical source, a growth chamber, a load lock chamber, and a vacuum system, whereby it is possible to manufacture a high quality oxide film at a low temperature and improve a low frequency noise (1/f).

### BACKGROUND

1. Field of the Invention

The present invention relates to an oxidation apparatus for manufacturing a semiconductor device and, more particularly, to a radical assisted oxidation apparatus capable of growing an oxide film with a high quality at a low temperature.

2. Discussion of Related Art

A process for manufacturing a silicon semiconductor has been developed remarkably owing to a development of a new technology. In particular, a necessity for a CMOS device employing a SiGe has been increased, as markets of a high performance microprocessor and a radio communication are getting broader. In the CMOS device, an operation characteristic of a MOSFET comprising a metal, an oxide, a silicon (Si), etc. depends on a characteristic of a gate dielectric film. The dielectric film is mainly formed with an oxide or a nitride, and a development for process technology has been required to improve an interface characteristic and state of the dielectric film.

An oxide film is considered to be important in a memory industry as well as a MOS structure. A dielectric thin film for a memory device requires a condition different from that of the gate dielectric thin film. In the case of the gate dielectric thin film, appropriateness with a lower silicon (Si) and stability of an interface are required. However, in the case of the dielectric thin film for a memory device, a leakage current characteristic or a dielectric constant (k) is considered to be more important than the interface state with a lower electrode. Therefore, dielectric materials and process conditions should be selected as required. In addition, a growth system and a technology, which can be applicable to a structure variation of a material in a process variable and a level of atomic layer, are required.

As a technology for manufacturing the CMOS device goes into Sub-100 nm or less, the thickness of the gate oxide film further decreases, and at present, a research and development have been achieved mainly in 1.0 nm grade. However, if the thickness of the gate oxide film becomes thinner as described above, it is impossible to control a diffusion of an impurity from a polycrystalline gate, a tunneling current, an impurity of an interface, and a defect such as a pit or a pipe, thereby reaching a physical limitation. Particularly, in the case of a device having a SiGe hetero structure, a temperature for forming a gate oxide film should be lowered to control diffusion in a hetero junction. In the case of the CMOS device, a low temperature process would be required to precisely control an ultra shallow junction or a pocket hallo.

Generally, a low temperature thermal oxidation process widely in use is carried out in a furnace having a temperature of 700° C., and a rapid thermal oxidation (RTO) process is carried out at a temperature of 900° C. However, since the above thermal oxidation processes are not suitable for manufacturing a device using SiGe, a method for forming a laser oxide film, plasma anodization, electrochemical anodization, a method for forming an ozone oxide film, etc. have been studied.

Meanwhile, a defect density should be lowered by keeping an interface state of a high quality to grow an oxide film having a low frequency noise and a superior leakage current characteristics (referring to “Development of high performance SiGe pHMOS with small 1/f noise levels and large signal CMOS integrity”, Solid-State Technology, 2003, written by K. H. Shim, Y. J. Song, and J. Y. Kang).

An oxide film grown by an UV laser or an electrochemical anodization method is porous and a structure thereof is not dense, so that the film has many defects, whereby there has been a difficulty in applying the film to practical use. Meanwhile, an electron cyclotron resonance (ECR) plasma method can be employed at a temperature of 450° C. or less to grow an oxide film having a relatively uniform interface. However, there have been some problems that GeO₂/SiO₂ layer is formed separately, Ge metal is precipitated, and a crystal defect may be generated due to a high-energy ion. In addition, it has the same property as an intrinsic semiconductor since an oxide layer of which an interface has many silicones exists in an upper layer and a lower layer of the gate oxide film with a thickness of 0.5 nm, respectively. And, it is supposed that there is a limitation in reducing the thickness of the oxide film to 1 nm or less, since an inversion layer having a thickness of about 3 nm is formed in a polycrystalline direction of the gate. As a result, such a problem still remains that a depletion layer existing at an interface with a channel has a thickness of 0.3 to 0.6 nm, although a metal gate is employed.

As described above, many similar methods have been suggested and used in a Si/SiGe hetero junction semiconductor device. However, there still remains a limitation in improving the quality of the oxide film, which has the thickness of several atomic layers. As an example, there was a prior art in which a radical is employed by decomposing a gas, however, it was not perfect in manufacturing a device having a superior performance. Meanwhile, if a conventional method for forming an oxide film is applied to a silicon germanium (SiGe), which is employed for a hetero junction quantum device, there is a problem that a germanium (Ge) moves into an interface and a precipitation would be generated (referring to “Effects of Si-cal layer thinning and Ge segregation on the characteristics of Si/SiGe/Si heterostructure pMOSFETs, Solid-State Electronics, 46, 2002, written by Y. J. Song, J. W. Lim, J. Y. Kang, and K. H. Shim).

FIG. 1 is a schematic view of a furnace for an oxidation process according to a conventional art using a plasma source.

A wafer 3 is placed inside a quartz tube 2 in which a hot wire 1 is equipped. Various kinds of atoms or molecules are provided by means of a plasma 4 using an RF inductance coil, ECR, or high voltage discharge so that particles having a high reactivity accelerate an oxidation reaction at a surface of the wafer 3. By using the aforementioned method, several wafers could be managed at the same time and a reaction gas could be generated with a high efficiency. However, it is difficult to form an insulation film having a high purity due to an implantation of impurities resulting from repeated uses of plasma. Thus, at present, it cannot be applied to the product.

FIG. 2 is a schematic view of a furnace for an oxidation process according to a conventional art using a direct irradiation of an UV lamp.

A wafer 13 is placed inside a tube 11 in which an IR lamp 16 and an UV lamp 17 are equipped. The UV lamp 17 is further equipped in the rapid thermal treatment apparatus composed of the IR lamp 16, which is mainly a sort of tungsten, and irradiated to the wafer 13, so that a plenty of reactive radicals are generated and a reaction may be accelerated (referring to “Ultraviolet Light Stimulated Thermal Oxidation of Silicon”, Appl. Phys. Lett. 50, 80, 1987, written by E. M. Young et al.). According to the method, the rapid thermal treatment can be performed and the speed of the reaction can be increased by generating the radical at the surface of the wafer. However, it has demerits that it is difficult to generate the radical uniformly on the wafer and a Si—Si bonding of the surface may be rapidly broken due to a radical having a high energy. In other words, the IR lamp 16 should be arranged densely in order to keep the temperature of the wafer constant. In this case, it is difficult to effectively arrange the UV lamp 17 on the tube 11 or around the tube 11. In addition, it is difficult to design a metal plate housing having a high reflectance to an optimized structure. Further, a bonding between atoms may be broken or unstable at the surface of the wafer since a radical or an ion having a high energy is directly irradiated thereto. Thus, a defect such as a fixed electron may be implanted to the oxide film.

FIG. 3 is a schematic view of a furnace for an oxidation process according to a conventional art using a flat plate plasma.

A lower electrode 28 and an upper electrode 27 are placed inside a chamber 21. In the lower electrode 28 and the upper electrode 27, an RF power supply for forming plasma 24 is supplied from an RF power supplier 29.

The RF power supply is supplied to the upper electrode 27 from the RF power supplier 29, while a wafer being placed on the lower electrode 28, so that plasma is formed inside the chamber 21. At this time, a gas is fed through a shower head of the upper electrode 27, the wafer 23 is maintained at a proper temperature by a heater 22 that is equipped on the lower electrode 28, whereby a reaction takes place actively. Like the conventional methods, the above method has a problem that a defect may be implanted during forming a thin film since a radical or an ion having a high energy is directly irradiated to the surface. Furthermore, various kinds of impurities, which are left remained by plasma during a growth of the thin film, are implanted, so that a film having a high concentration of an impurity may be grown. Therefore, there has been a limitation in forming a dielectric film with a high purity and quality. In addition, the rapid thermal treatment using the IR lamp would be impossible since the upper electrode and the lower electrode are manufactured with a metal.

### SUMMARY OF THE INVENTION

The present invention is contrived to solve the aforementioned problems. According to a radical assisted oxidation apparatus of the present invention, a plenty of radicals are generated by irradiating a light having a short wavelength such as UV to a reaction gas, and components of the radicals and energy distribution are controlled by supplying the generated radicals to a growth chamber.

One aspect of the present invention is to a radical assisted oxidation apparatus, comprising: a gas supply system for supplying a plurality of reaction gases; a radical source for generating a radical by decomposing the reaction gas supplied from the gas supply system; a growth chamber for receiving the radical and the reaction gas, and having a plurality of lamps for heat treatment; a load-lock chamber for transferring a wafer to the growth chamber; and a vacuum system for making an interior of the growth chamber vacuum state and exhausting the reaction gas.

In a preferred embodiment of the present invention, a control system for controlling operations of the gas supply system, the radical source, the growth chamber, the load lock chamber, and the vacuum system may be further included. And, a transfer arm for transferring the wafer is equipped in the load lock chamber, and a thermocouple for heating the wafer is attached to the transfer arm.

Here, the plurality of lamps may be an IR lamp and an UV lamp. The gas supply system comprises a plurality of gas supply lines to which the plurality of reaction gases are supplied respectively, and a flow regulator and a gas valve being equipped in each of the gas supply lines. A chamber for a surface treatment of a wafer is connected to the load lock chamber through a cluster. And the reaction gas comprises O₂, N₂, Ar, N₂O, NO₂, NH₃, H₂, HfCl₄, ZrCl₄, and TMA (Al).

In a preferred embodiment of the present invention, the radical source comprises an outer cover in which a gas injection port and a gas exhaust port are formed; a plurality of lamps being inserted into the outer cover and separated each other by a reflection film; a plurality of electrodes for supplying a power supply to the plurality of lamps, respectively; and coil shaped gas lines, of which both side edge portions are connected to the gas injection port and the gas exhaust port, respectively, and being equipped so that the reaction gas circulates around the lamp. Further, the radical source may comprise sensors for monitoring states of the reaction gas and the lamp.

Meanwhile, the vacuum system comprises a gas exhaust line being connected to an exhaust port; a gas exhaust line being connected to a pumping system; a chamber separation valve for connecting each of the gas exhaust lines to the growth chamber, and separating the gas exhaust lines from the growth chamber; and a plurality of valves being equipped in each of the gas exhaust lines.

### BRIEF DESCRIPTION OF THE DRAWINGS

The aforementioned aspects and other features of the present invention will be explained in the following description, taken in conjunction with the accompanying drawings, wherein:

FIG. 1 is a schematic view of a furnace for an oxidation process according to a conventional art using a plasma source;

FIG. 2 is a schematic view of a furnace for an oxidation process according to a conventional art using a direct irradiation of an UV lamp;

FIG. 3 is a schematic view of a furnace for an oxidation process according to a conventional art using a flat plate plasma;

FIG. 4 is a block diagram of a radical assisted oxidation apparatus according to a preferred embodiment of the present invention;

FIGS. 5A and 5B are schematic views for explaining a principle of a radical formation;

FIG. 6 is a graph for explaining a radical formation according to a variation of energy;

FIGS. 7A to 7D are schematic views for explaining a constitution of the radical source shown in FIG. 4;

FIG. 8 is a graph showing a variation of a thickness depending on a time, in case where an oxide film is grown by a radical assisted oxidation apparatus of the present invention; and

FIG. 9 is a conceptual view showing a bonding at an interface between an oxide film and a silicon germanium (SiGe), and a non-uniform distribution.

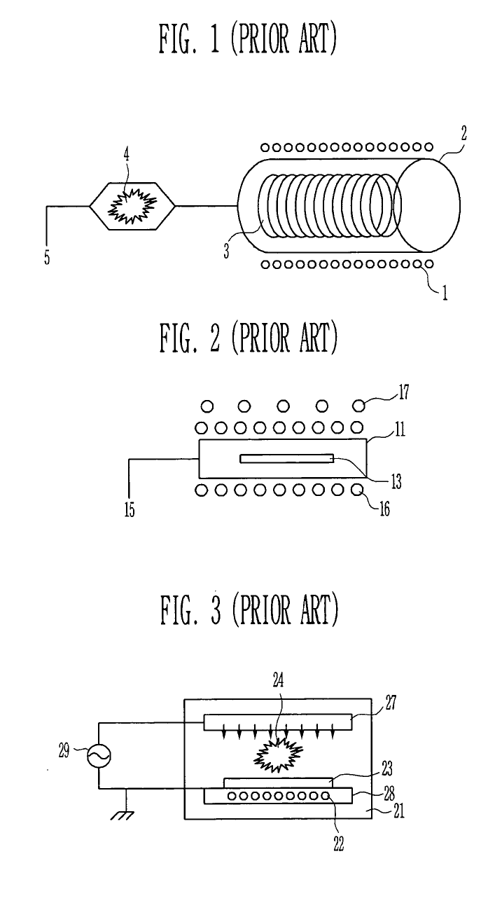

### DETAILED DESCRIPTION OF PREFERRED EMBODIMENTS

Now, the preferred embodiments according to the present invention will be described with reference to accompanying drawings. Since preferred embodiments are provided for the purpose that the ordinary skilled in the art are able to understand the present invention, they may be modified in various manners and the scope of the present invention is not limited by the preferred embodiments described later.

In an integration of a semiconductor device, a primary variable of a scaling factor (1/α) related to a decrease of a device size may be a gate length and width. Thus, a degree of integrity increases proportional to α², power consumption decreases proportional to

$$\frac{1}{{α}^{2}}$$

since a driving voltage (V_{gs}−Vₜₕ) is controlled to have a small value, and an operation speed would be improved. A drain saturation current in a channel of a device could be represented as follows in Equation 1;

$${I}_{D , sat} = \frac{W}{L} μ {C}_{inv} \frac{{( {V}_{GS} - {V}_{th} )}^{2}}{2 n} \qquad 〈 Equation 1 〉$$

Where, n=1+C_{d}/C_{OX}, SS(mV/dec)=n(kT/q)ln(10). A subthreshold swing (SS) would be approximately 60 mV/dec in the ideal case of n=1, however, it increases considerably as a device size decreases to Sub-100 nm grade. If the SS increases only about 20 mV/dec, I_{off} soars exponentially up to 15 times. Thus, a channel structure and a quality of an oxide film would be important.

In order to decrease power consumption, V_{DD} and Vₜₕ should be decreased. Since a thermal energy may be 20 mV at a room temperature, the minimum Vₜₕ will be approximately 200 mV. Recently, an effort for decreasing the thickness of the gate dielectric thin film to several nm grades has been made, as a driving voltage of a device has been decreased by 1 V or less.

By controlling Cᵢₙᵥ and a gate length, and keeping drain conductivity high, the characteristic of Gₘ/Gₒᵤₜ>1 can be adapted to a circuit. A junction capacitance of a gate becomes

$${c}_{ox} = \frac{k {ɛ}_{o} A}{{t}_{ox}} ,$$

which corresponds to a value by an oxide film gate, in the state of a channel being inversed. Thus, many efforts to employ a metal-oxide film, of which a dielectric constant (ε ˜25) is higher than that of an oxide film (ε ˜3.9), as an ultra thin film gate dielectrics have been tried. Moreover, a trial for solving the problem of a thermal oxidation film according to a prior art has been made by growing a metal-oxide film with several nm grades and controlling a leakage current to 1 A/cm² or less, at the same time. Therefore, the growth technology of the gate dielectric thin film will be important factor that decides a technology level of integrating a device, in future.

In order to prevent a variation of a critical voltage due to a diffusion of boron (B) and a non-uniformity of a thickness, and a decrease of a breakdown voltage due to a leakage current, a trap of a high-energy electron hole in a MOS structure, a thickness of a silicon oxide film should be confined to about 1.5 nm. Thus, it is inevitable to develop a substitutional oxide film for developing a device suitable for a designing standard of 0.1 μm or less. Recently, a study for a high-k metallic oxide film has been focused, wherein the high-k metallic oxide film is expected to reduce power consumption by decreasing a leakage current of a gate and improving a device performance by increasing a junction capacitance of a gate.

A development for a gate dielectric film has been started from a basic operation principle of the MOS device. In other words, a flat-band voltage is determined by Q_{f} existing in a gate dielectrics film as follow in equation 2.

$${V}_{FB} = {ϕ}_{MS} \pm \frac{{Q}_{f}}{{C}_{ocr}} \qquad 〈 Equation 2 〉$$

Where, + corresponds to a negative charge and − corresponds to a positive charge. Since power consumption and a shift of Vₜₕ could be reduced when V_{FB} is small, a fixed charge existing in dielectrics should be remained with a low concentration. A critical voltage in the MOS structure is determined by a difference of a work function and a concentration of a channel. In the case of an nMOS in a Sub-100 nm grade technology, it has a disadvantage of decreasing V_{FB}, Φ_{MS} since a critical voltage reaches N_{A} ˜10¹⁹ cm⁻³. Under the background as mentioned above, the performance of the gate dielectric film depends on the main characteristics as follow, according to a long-studied result.
1) a variation of dielectricity by diffusion of phosphorous (P) or boron (B) through an interface charge or a gate insulation film: <20 mV,
2) a density of a interface charge: <10¹⁰/cm² eV,
3) a leakage current of a gate: <10⁻³ A/cm² @V_{GS}=V_{FB}+1V),
4) a leakage current according to a voltage stress: stress induced leakage current (SILC).

The aforementioned problems have not solved yet and would be a main cause of deteriorating a device characteristic, in the case of a short channel transistor. Therefore, in order to solve the problems of the prior art, a new method that an oxide film having a high quality can be formed on a surface of a wafer at a low temperature has been required.

Hereinafter, a preferred embodiment of the present invention will be explained in detail with reference to the attached drawings.

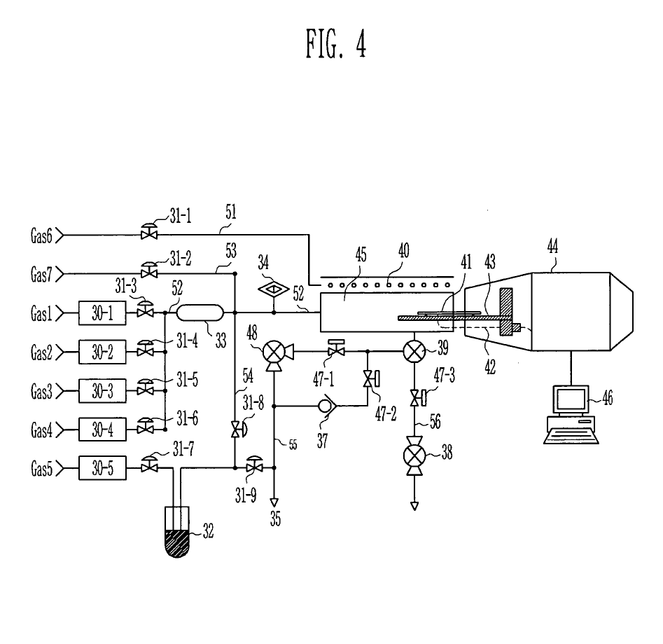

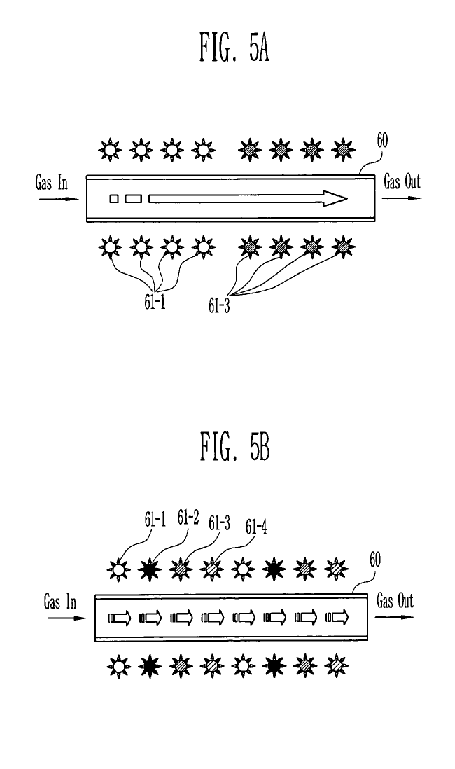

FIG. 4 is a block diagram of a radical assisted oxidation apparatus (RAO) according to a preferred embodiment of the present invention.

A radical assisted oxidation apparatus of the present invention comprises a growth chamber 45 in which a number of UV and IR lamps 40 for a rapid thermal treatment are equipped, a load-lock chamber 44 for transferring a wafer 41 to the growth chamber 45 by using a transfer arm 43 in which a thermocouple 42 is attached, a gas supply system for feeding a reaction gas into the growth chamber 45, an vacuum system for making an interior of the growth chamber 45 vacuum state and exhausting the reaction gas, and a computer control system 46 for controlling the above operations automatically.

The load-lock chamber 44 has a cluster type, so that the wafer 41 may be surface-treated in a chamber (not shown) for cleaning a wafer, and then, thrown into the load-lock chamber 44 through a cluster. At this time, the degree of vacuum and the cleanness of the load-lock chamber 44 should be kept to protect the surface of the wafer 41 completely after cleaning of the wafer 41. A wet or a dry surface treatment is considered as an important step for making a quality of a silicon-oxide film interface the best.

The gas supply system comprises a plurality of gas supply lines, into which many kinds of gases Gas 1 to Gas 7 are fed, flow regulators 30-1 to 30-5 each being equipped in the gas supply lines, and gas valves 31-1 to 31-9.

In order to prevent an over heating of the chamber, the gas Gas 6 is introduced into the growth chamber 45 through a gas supply line 51 in which the gas valve 31-1 is equipped. The various kinds of gases Gas 1 to Gas 4 for generating a radical gas are supplied into a radical source 33 through a gas supply line 52 in which the flow regulators 30-1 to 30-4 and the gas valves 31-3 to 31-6 are equipped, respectively. And the radical that is generated by decomposition of the reaction gas in the radical source 33 is fed into the chamber 45. The gas Gas 7 is introduced into the gas supply line 52 through a gas supply line 53 in which the valve 31-2 is equipped, and the gas Gas 5 for a liquid source being used in a wet oxidation is supplied into a liquid evaporation source 32 through the flow regulator 30-5 and the gas valve 31-7, and the gas supply line 52 through a gas supply line 54 in which the gas valve 31-8 is equipped. A gas analyzer 34 is connected to the gas supply line 52 that is placed in an entrance of the growth chamber 45, and the gas supply line 54 is connected to an exhaust port 35 through the gas valve 31-9.

As described above, in the present invention, the gas is fed into the growth chamber 45 through the plurality of valves 31-1 to 31-9 and the gas supply line. At this time, the gas may be fed into the growth chamber 45 directly or via the radical source 33. Therefore, not only a crystal structure of an oxide film but also a characteristic of an electric optical material could be controlled. In addition, a thickness of an oxide film can be controlled precisely to a level of several atomic layers by employing various control methods for supplying gases and a rapid thermal treatment. In particular, the gas may be supplied with in-line, so that it functions as an ultra clean source having a very small quantity of carbon (C) or impurities (<10¹³ cm⁻³), which are a sort of a metal.

The vacuum system comprises a gas exhaust line 55 being connected to the exhaust port 35, a gas exhaust line 56 being connected to a pump valve 38, and a plurality of valves each being equipped in the gas exhaust lines 55 and 56. The growth chamber 45 is controlled to have an inner pressure in the range of 1 to 760 Torr. Each of the gas exhaust lines 55 and 56 is separated from the growth chamber 45 and connected thereto by means of a chamber separation valve 39. An automatic control vacuum valve 47-1 and a vacuum valve 48 are equipped in the gas exhaust line 55, and a safety valve 37 and an automatic control vacuum valve 47-2 are equipped in the vacuum valve 48 in parallel. An automatic control vacuum valve 47-3 and the pump valve 38 are equipped in the gas exhaust line 56.

Now, a process for manufacturing an oxide film using the aforementioned radical assisted oxidation apparatus will be explained as follow.

The pressure inside the load-lock chamber 44 is controlled to 10⁻⁷ torr or less and the growth chamber 45 is connected to a sealing and a turbo pumping system to make the pressure thereof about 10⁻⁹ torr. The wafer 41 is transferred into the growth chamber 45 by the transfer arm 43 inside the load-lock chamber 44. The temperature of the wafer 41 is measured, when being transferred, by means of an optical sensor that is installed in the thermocouple 42 attached to the transfer arm 43, or outside the chamber.

The gas Gas 6 for preventing an over heating is fed into the growth chamber 45 by opening the valve 31-1, and the reaction gases Gas 1 to Gas 4 are supplied to the radical source 33 by opening the valves 31-3 to 31-6. In the radical source 33, the reaction gases Gas 1 to Gas 4 are decomposed to generate radicals such as O₃, activated atoms, etc., and then, supplied into the growth chamber 45. At this time, the generated radical passes deozonizer to be in a state of a normal molecule. In addition, by operating a gas analyzer 34 and measuring the kinds and partial pressures of the radicals, gas atoms, and molecules that are supplied through an UV zone, a process could be precisely controlled.

At a low temperature of 400° C. or less, O₃ accelerates a surface oxidation thereof to form an uniform oxidation film densely. If the partial pressure of O₃ is increased, it becomes easier to form an oxide film. In the case of using the plasma method in which O₃ is generated with a high efficiency, it is difficult to supply an ultra clean O₃ gas due to impurities. However, a SiGe MOS device can be obtained with an excellent interface characteristic, if an ozonizer using an UV lamp is employed, an O₃ oxide film is formed at an interface with a low temperature in ultra-high vacuum (UHV), and a silicon oxide (SiO₂) is grown sequentially.

Preferably, the reaction gas for growing a gate insulation film such as a silicon oxide film or a silicon nitride film may be, for example, O₂, N₂, Ar, N₂O, NO₂, NH₃, H₂, etc. In addition, if a gas supply system is made to supply HfCl₄, ZrCl₄, and trimethylaluminum (TMA (Al)) gases repeatedly, which are necessary to grow a reaction gas and a metallic oxide film such as Hf, Zr, Al, and Ti, a high-k film can be grown to have a stacked structure.

Referring to reaction equations 1 and 2, Al₂O₃ could be formed, as follow, by a reaction of H₂O or O₃ with TMA, which becomes a source of Al.
2Al(CH₃)₃+3H₂O→Al₂O₃+6CH₄ <Reaction equation 1>
2Al(CH₃)₃+O₃→Al₂O₃+3C₂H₆ <Reaction equation 2>

In the case of forming Al₂O₃ with a high quality by the above reactions 1 and 2, it has been found that the amount of remaining carbon (C) would be little and the quality of Al₂O₃ interface becomes better by using O₃ rather than H₂O.

Hereinafter, radicals being used for oxidation and the radical source 33 for generating the radicals of the present invention will be explained in detail.

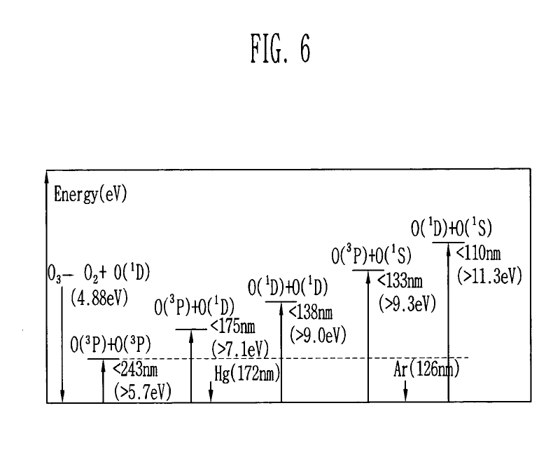

FIGS. 5A and 5B are schematic views for explaining a principle of a radical formation, by using various kinds of lamps each having a different wavelength.

Referring to FIG. 5A, two kinds of lamps 61-1 and 61-3 are placed outside a quartz tube 60 in a series. In this case, a radical and a component of the final gas are controlled by a decomposition method having characteristics of two steps.

Referring to FIG. 5B, four kinds of lamps 61-1 to 61-4 are placed outside the quartz tube 60 with a combination thereof. In this case, the component and energy state of the radical are determined by the finally supplied gas.

If each of the power supplies in the lamps 61-1 to 61-4 is controlled automatically by using of a computer and the like, process conditions can be changed flexibly when performing a multi-step process sequentially, thereby it can be applied for developing technology. By using the UV lamps, which generate a light having a different wavelength and intensity, it is possible to control the formation efficiency of the radical by kind. A physical characteristic related to a growth of an insulation film according to the partial pressure of the radical is very important in the development of nano-grade new device having a hetero junction quantum well, which is sensitive to a temperature like a Si/SiGe.

FIG. 6 shows that an oxygen gas is activated to a high-energy state according to a variation of energy, and thus, the radicals are formed.

An oxygen molecule is decomposed in the lowest energy of 5.7 eV (243 nm) and a radical of O(¹S) having high-energy can be generated up to in high-energy of 11.3 eV (110 nm). The distributions of the aforementioned energy and the radical could be controlled by constituting the lamps as shown in FIGS. 5A and 5B. The energy state of the radical and the density distribution decide quality of an oxide film requiring interface flatness of an atomic level. In the case of applying UV as described in FIG. 6, oxygen atoms having various kinds of energy states, as described in Reaction equations 3 to 5 as follows, are generated by decomposition of the oxygen molecule by means of UV each having a different wavelength.

$$\begin{matrix}1.110 nm < λ < 133 nm & 〈 Reaction equation 3 〉 \\ {O}_{2} ( {\sum }_{g}^{3 -} ) + h ν -> O ( {}^{3} P ) + O ( {}^{1} S ) , & \\ Δ {H}_{0} = 897.80 \text{kJ/} mol & \\ 2.138 nm < λ < 175 nm & 〈 Reaction equation 4 〉 \\ {O}_{2} ( {\sum }_{g}^{3 -} ) + h ν -> O ( {}^{3} P ) + O ( {}^{1} D ) , & \\ Δ {H}_{0} = 683.38 \text{kJ/} mol & \\ 3.200 nm < λ < 243 nm & 〈 Reaction equation 5 〉 \\ {O}_{2} ( {\sum }_{g}^{3 -} ) + h ν -> O ( {}^{3} P ) + O ( {}^{3} P ) , & \\ Δ {H}_{0} = 493.56 \text{kJ/} mol & \end{matrix}$$

As described in Reaction equations 3 to 5, if the wavelength of UV being irradiated to gases decreases from 172 nm (Hg eximer lamp) to 126 nm (Ar eximer lamp), an absorption area of the oxygen molecule increases from 10 to 600 atm⁻¹ cm⁻¹. In the case of O(¹S) and O(¹D), it has been kwon that the speeds for recombination and formation of the oxygen molecule, at a room temperature, are 3.6×10⁻¹³ and 4.1×10⁻¹¹ cm³ mol⁻¹s⁻¹, respectively. Therefore, it is more advantageous to employ the Ar eximer lamp rather than Hg eximer lamp. In the case of using the Ar eximer lamp, the oxidation rate can be increased 10 to 100 times, by oxidizing with 20% O₂ (in Ar) under energy of 100 mV/cm² and a pressure of 100 mbar. However, since Si—Si bonding would be broken increasingly at the surface of the wafer by oxygen, which is extremely activated by UV having a wavelength of 126 nm, formation of an interface having a high quality may be difficult. In addition, the generated oxygen atom forms ozone by reaction equation 6 as follows, and the resultant ozone is decomposed by means of an endothermic reaction or UV as described in reaction equations 7 and 8.
O(³P)+O₂→O₃ <Reaction equation 6>
O₃→h [symbol] (254 nm=4.88 eV)→O₂+O(¹D) <Reaction equation 7>
O₃→O₂+O (ΔH⁰=1.07 eV) <Reaction equation 8>

In the case of the Hg lamp, which has been widely used, a beam having an energy density of 25 mWcm⁻² or more is irradiated so that a main peak and a second peak become 254 nm (4.88 eV) and 185 nm (6.70 eV), respectively, whereby it is possible to reduce formation of a radical having a high-energy.

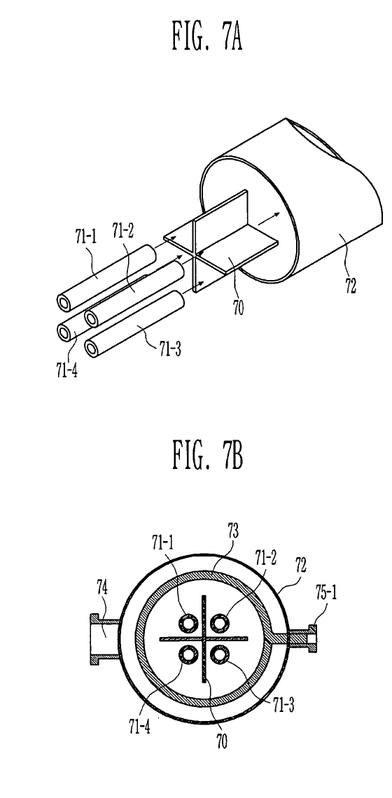

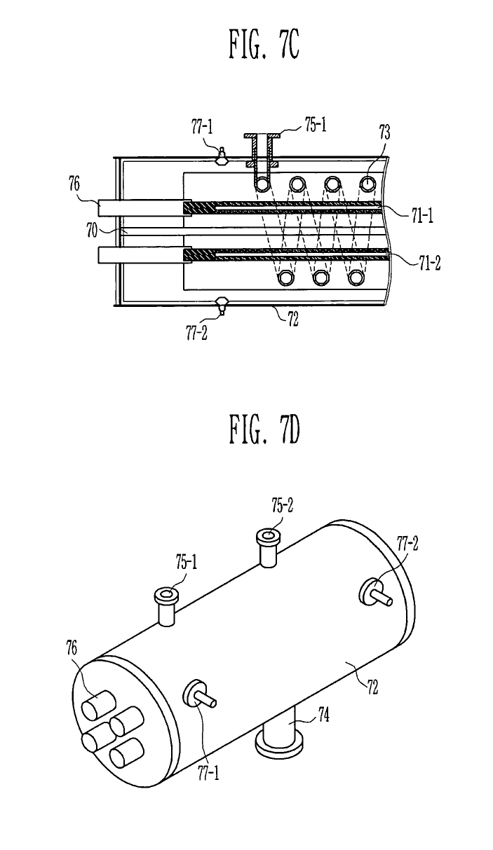

FIGS. 7A to 7D are schematic views for explaining a radical source 33 of the present invention. Now, an embodiment having various kinds of lamps will be described.

Four kinds of lamps 71-1 to 71-4 being separated each other by a reflection film 70 are inserted inside an outer cover 72 having a cylinder shape. A reaction gas, which is injected via a gas injection port 75-1 formed in the outer cover 72, is exhausted to a gas exhaust port 75-2 through a gas line 73 installed with a coil type, in order to circulate around the lamps 71-1 to 71-4. When the gas injected through the gas injection port 75-1 passes the gas line 73 having a coil shape, various radicals are generated by decomposition of the gas due to a light being irradiated from the lamp 71-1 to 71-4, respectively. At this time, if an air is introduced around the lamps, the generated radicals may be released to the outside. Therefore, to prevent this, ozone and NO sensors may be installed to monitor the degree of vacuum of the radical source all the time. If the inner modules having the lamps 71-1 to 71-4 are remained at a low vacuum state by operating a vacuum port 74, ozone is not released to the outside, thereby efficiency of supplying the radical could be increased and the safety could be insured. The radical source 33 as described above is the same as the radical generator in which various kinds of lamps are arranged repeatedly as shown in FIG. 5B.

Referring to FIG. 7C, sensors 77-1 and 77-2 are attached to the edges of the inner modules so as to monitor the gas injection port 75-1 and the lamps 71-1 to 71-4. The lamps 71-1 to 71-4 are connected to electrodes 76, respectively, and receive power supply individually. Each of the lamps 71-1 to 71-4 operates while being controlled individually according to a time and a power supply that are selected with real time via power suppliers each being connected to computer. At this time, a power supply for generating ozone is controlled in the range of approximately 10 to 400 W grade, and energy density irradiated to the gas line 73 is controlled to 10 mW/cm² or more. If different kinds of lamps are arranged in a series, component of the radical can be controlled more precisely.

Each of the sensors 77-1 and 77-2, the vacuum port 74, and the gas injection port 75-1 are equipped so that a light being irradiated from UV lamps 71-1 to 71-4 is normally focused on the gas line 73 as much as possible. The vacuum port 74 or the gas injection port 75-1, and the gas exhaust port 75-2 are placed not to be matched with the lamps 71-1 to 71-4, and at the same time, a parts serving as a reflector is equipped in the front portion of the port so that a constant light is uniformly irradiated.

FIG. 8 is a graph showing a variation of a thickness depending on a time, in case where an oxide film is grown by a radical assisted oxidation apparatus of the present invention.

As shown in FIG. 8, the oxide film is grown to have a thin thickness of about 0.8 nm at a low pressure of 40 torr, as compared with a high pressure of 940 torr, and a growth rate thereof is constant according to a variation of time. If the reaction gas is supplied, while transferring the wafer into the growth chamber 45 and increasing the temperature, it can be noted that an oxide film having a thickness of about 2 nm has already been grown at a temperature lower than a growth temperature. The aforementioned embodiment is performed such a mode that the oxide film is grown at a temperature lower than a growth temperature. However, an oxide film having a thickness of 1 nm or less can be obtained by maintaining the growth chamber 45 at a high vacuum state and increasing a temperature with an injection of a non-reaction gas. Therefore, an oxide film was grown to have a thickness of 1.5 to 4 nm, and a leakage current and breakdown voltage were similar to those of the high temperature thermal oxide film, even though the growth chamber is not maintained at a high vacuum state. In other words, it has been confined that a breakdown field is a high value of about 12 MV/cm and a variation of a tunneling current is accordance with the value measured in the thermal oxidation within the range of an error. Thus, a low temperature oxide film having a thickness of 1 nm or less can be grown with a high quality by keeping a high vacuum state at the initial state.

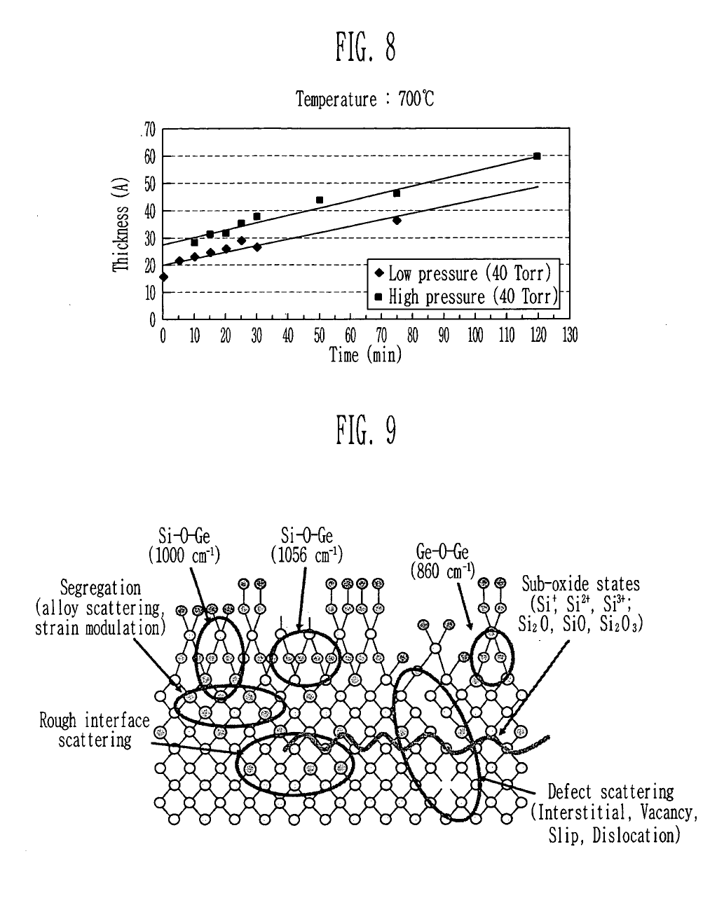

FIG. 9 is a conceptual view showing a bonding at an interface between an oxide film and a silicon germanium (SiGe), and a non-uniform distribution.

It has been known that a thickness of a shift layer decreases, and thus, an oxide film can be formed with a high quality, since ozone decreases a thickness of a suboxide being grown at an interface particularly. Further, it has been found that activation energies being required for oxidizing silicon (100), in the case of an oxygen molecule, are E=0.2 (fast) eV and E=0.36 (slow) eV in an initial fast reaction and a later low reaction, respectively. In the case of ozone, E=0.13 (fast) eV and E=0.19 (slow) eV, respectively. Therefore, an oxide film can be formed at a relatively low temperature with an appropriate growth rate, by employing ozone. Flatness and defect density at an interface between the oxide film and the semiconductor affect a mobility of a carrier directly. In addition, if a segregation of a germanium (Ge) atom becomes severe at a high temperature, an alloy scattering increases. Thus, the oxide film could be formed rapidly; the growth rate of the suboxide would be low; the shift layer may be thin; a thickness is uniform; and a defect due to a collision of an ion may not occur, in the case of using ozone.

Referring to FIG. 9, a high temperature heat treatment causes a stress relaxation in a SiGe hetero structure or a mutual diffusion at an interface. In addition, a germanium oxide (GeO₂) would be formed at an unstable state and an interface defect would be generated with a high density since a large quantity of Ge metals are precipitated below the oxide film (referring to “a growth of an ultra thin film gate oxide film having a high quality by a low temperature radical oxidation method, and a method for manufacturing a CMOS having a silicon-germanium hetero structure by using the same”, electric and electronic material paper, 2003). Therefore, for a practical use of a SiGe MOSFET, a technology for forming a high quality MOS gate should be developed. In particular, suboxides (Si⁺, Si²⁺ and Si³⁺) cause a trapping-detrapping, which may be generated within 1 nm region from an interface, resulting in a low frequency noise. The low frequency noise (1/f) would be generated due to an imperfect bonding of silicon (Si) that generally exists in a gate oxide film within 1 nm from a channel, and extremely deteriorates a noise performance at a high-speed circuit of the CMOS device. By using a low-pressure radical assisted oxidation (LP-RAO) that controls a partial pressure of a reactive gas at an interface when forming an oxide film, a defect density at an interface can be reduced, thereby remarkably improving a low frequency noise characteristic. Particularly, if a gate area decreases by 0.1 μm² or less, a very small amount of a random telegraph signal (RTS) in the low frequency noise (1/f) generates extremely, so that a signal is changed considerably. Therefore, a high quality oxide film becomes more important with a decrease of a size in a gate of the CMOS device.

A balance band offset of SiO₂/Si may be measured in the range of 4.3 to 4.49 eV according to a method for forming on oxide film. Si⁺ and Si³⁺ of suboxide reduce the band offset of a baseband by making a dipole of an interface small by means of a polarization. In addition, a pinhole is generated in an oxide film having a thickness of 1 to 2 nm and acts like a path of a leakage current and a weak breakdown. When forming the oxide film having the thickness of 1 to 2 nm in a furnace, there has been a difficulty of increasing temperature rapidly. In particular, a dangling bond of ═Si— acts as a defect at 0.3, 0.5, and 0.7 eV being located above the baseband, thereby causing a hopping conduction tunneling. In general, if a fixed charge of [Hf═OH]⁺ ion group exists in an interface, a mobility of a carrier would decrease. Therefore, the fixed charge should be removed by generating [H₂O] with ozone (O₃).

In the case of the thermal oxidation film, an interface state gets deteriorated, as the heat treatment temperature becomes 800° C. or less. Therefore, the present invention is particularly beneficial in case where there is a limitation in a heat treatment, resulting from a high mobility channel of a hetero structure SiGe. For a high-speed operation, a gate length should be short and a gate oxide film should be replaced by a high-k metallic oxide film, at the same time. According to the present invention, diffusion or segregation of Ge is prohibited at a SiGe/Si interface and Si—Ge—O can be manufactured with a high quality. It may be an important subject that the high-k metal-oxide film is realized in the device, which adapts a MOS structure in a SiGe HFET. However, it is important to keep a compatibility with the CMOS device and a high quality interface when applying the high-k film to the gate, since the mobility of the channel carrier may be reduced to a half.

According to the present invention, an interface density of the gate oxide film can be reduced. Meanwhile, a Si thermal oxidation film of an amorphous, which is grown thermally, has an excellent interface characteristic, a little leakage current, and a low defect electric charge density. Generally, it has been required a density of about 10¹⁰/cm² eV. However, the thickness of SiO₂, which has been required in the device, decreases to 20 Å or less with a high integration and it is expected to decrease by 10 Å or less in future. According to a theoretical study, it has been known that the minimum thickness for keeping a bulk characteristic is 7 Å. If the thickness is 7 Å or less, the SiO₂ cannot function as a dielectrics due to a short. However, even in case where the thickness is 7 Å or more and 20 Å or less, a tunnel current effect may be shown, resulting in a soft-breakdown. As a result, reliability of the device could be deteriorated. It has been reported that a leakage current characteristic would be improved in the case of using a nitric oxide, a pure Si₃N₄ has a dielectric constant (k) of about 7 and a penetration of boron (B) could be reduced. According to the report, adding a few nitrogen (N) may be effective, however, a lot of N may cause deterioration of the device due to an excess charge by a five-valence nitrogen atom and a defect at an interface. Therefore, a technology of adding a few N and easily controlling a composition thereof is required. In addition, a distribution of composition should be finely controlled to deposit a more optimized oxide.

The nitric oxide described above has a limitation of reducing an equivalent thickness of a silicon oxide. Thus, a metal oxide having a higher dielectric constant (k) has been studied as a substitute oxide. A study for an oxide of Ta, Ti, etc. has been progressed but it reacts with Si at an interface, thereby deteriorating a characteristic of a device. Thus, a metal oxide, which is more stable thermodynamically and new, is required. As a result of growing an oxide such as Ta₁₋ₓAlₓO_{y} or Ta₁₋ₓSiₓO_{y} by adding a few Si or Al to TaOₓ, an amorphousness could be remained by increasing crystallization temperature and, an excellent characteristic and a surface shape could be obtained by relaxing SiO₂ formation, according to a recent preceding patent.

The present invention provides a growth of an oxide film and a stacked structure of a high-k metallic oxide film as an example for a metallic oxide film and a metal silicate.

As described above, formation of a pin hole and non-uniform thickness in an oxide film having a thickness of 1 to 2 nm may cause a soft-breakdown and, a point defect or a trap of an electric charge and a state density at an interface decide a characteristic of an oxide film. In the case of an oxide film having a thickness of about 1.5 nm, a leakage current may be ˜10 A/cm² and, in a thickness of 1 to 1.3 nm, a leakage current soars to 100 A/cm². Considering a deviation of a voltage, it is possible for an oxide film to have a thickness of 0.8 nm or less, but in view of a uniformity of a thin film and a roughness, a thickness may be confined to about 1.3 nm. From this point of view, the present invention may be very effective since a uniform oxide film is grown at a surface of a wafer by employing a radical at a low temperature. In particular, it is considered as an important technology that a silicon nitride film or a metallic oxide film such as Al, Hf, Zr, and Ti is grown with a cluster equipment while using a superior interface of a silicon oxide film.

A widely studied high-k film for a capacitor of a memory device may be Ta₂O₅ (k=20˜30), SrTiO₃, Al₂O₃ (k=8˜10), and so on. Al₂O₃ is stable thermodynamically and has been studied the most, so that it may be very likely to be adapted in the field of industry. However, it has demerits that phosphorus (P) is diffused through Al₂O₃ and a flat band is increased by trapping a negative charge of (Al—O) inside the dielectrics. Ta₂O₅ has a high dielectric constant. However, a transient current is caused by schottky characteristic since a defect band thereof exists close to a conduction band, resulting in damage. In addition, it is required to form an oxide film at a lower interface since it is crystallized at the time of a high temperature heat treatment.

As described in table 1, dielectric constants of metallic oxide film HfO₂, ZrO₂, Gd₂O₃, Y₂O₃ are 40, 25, 18, and 14, respectively. Since the metal-oxide film grown on the silicon is stable and has a crystal structure of a bulk, it should have higher dielectric constant. However, practically, the dielectric constants of metallic oxide films described above decrease, since a silicate layer may be formed by a reaction at an interface with silicon. In addition, there has been a difficulty in commercializing because unstable bonding and point defect exist at an interface with a metallic oxide films and the interior and, therefore, a trap exist. A trap having a time constant of a large value mainly affects a low frequency noise, so that it could be a fatal cause that a jitter noise in a digital circuit and a phase noise in an RF resonance circuit are increased. In Table 1, characteristics of materials having high-k are compared (referring to “Appl. Phys. 89, 5243 (2001)” written by G. D. Wilk, R. M. Wallace, and J. M. Anthony, J).

TABLE 1

| | | dielectric | | Δ E_{c} to Si | |
|---|---|---|---|---|---|
| material | | constant (k) | E_{g} (eV) | (eV) | crystal structure |
| Silicon | SiO₂ | 3.9 | 8.9 | 3.2 | α |
| | Si₃N₄ | 7 | 5.1 | 2. | α |
| IIIA | Al₂O₃ | 9 | 8.7 | 2.8 | α |
| IIIB | Y₂O₃ | 15 | 5.6 | 2.3 | Cubic |
| | La₂O₃ | 30 | 4.3 | 2.3 | Hexagonal, Cubic |
| V | Tr₂O₅ | 26 | 4.5 | 1˜1.5 | Orthorhombic |
| IVB | TiO₂ | 80 | 3.5 | 1.2 | Tetragonal |
| | HfO₂ | 40 | 5.7 | 1.5 | Mono., Tetra., |
| | | | | | Cubic |
| | ZrO₂ | 25 | 7.8 | 1.4 | Mono., Tetra., |
| | | | | | Cubic |

HfO₂ (k=40) is crystallized at a low temperature and stable with Si. As for a silicate, there are HfSiO₄ (k=15˜25) and Hf₆Si₂₉O₆₅ (k=11), Hf₆Si₂₉O₆₅ is remained in a state of amorphous even at 800° C. As for a Zr base, there are ZrO₂ (k=25), ZrSiO₄ (K=12.6), and Zr₄Si₃₁O₆₅ (k=9.5), and all of them have Dᵢₜ=10¹²/cm² and Iₗₑₐₖ=10⁻⁶ A/cm², and they are in an amorphous state. Gd₂O₃ (k=18) is flat, forms a sharp interface with Si, reduces a leakage current by 1/1000 times due to a crystallization thereof, and has an interface state density (Dᵢₜ) of approximately 10¹¹/cm². Y₂O₃ (k=14) is flat, forms a sharp interface with Si, has an interface state density (Dᵢₜ) of 10¹¹/cm², and is crystallized at 550° C.

A band gap of a High-k thin film is smaller than that of a silicon oxide film and an offset of a band becomes small, resulting in an increase of a leakage current. In addition, it is difficult to apply the high-k thin film to a gate due to some problems such as a variation of a critical voltage by a defect at an interface between dielectrics and silicon, a decrease of a mobility (μ/μ₀=1/(1+kDᵢₜ)), where k and Dᵢₜ are a proportional constant and an interface state density), a passing current through a trap inside the dielectrics, and a passing current by a decrease of band gap energy barrier layers of a baseband and a conduction band. In other words, an energy barrier layer between a conduction band and a baseband should be 1 eV or more, in order to prevent a possibility that a carrier penetrates a square energy barrier layer and a leakage current due to a thermionic emission. However, there is no perfect metallic oxide film, of which a dielectric constant and a band gap are large, an interface state density is low, and a stability is too high thermodynamically not to react with silicon. Therefore, a multilayered stacked structure that is coupled with oxide films each having an excellent characteristic may be beneficial practically.

Meanwhile, a silicon oxide film between a metal-oxide film and a silicon could be formed to have a thickness of several atomic layers since the silicon oxide film could be generated easily between a silicon and a metal-oxide film, and an interface state density shows a tendency to decrease. In a high performance professor, an allowable value of a leakage current is <10² A/cm² and, in a low power supply application, ˜10⁻³ A/cm². In particular, a radical assisted oxidation apparatus of the present invention can be applied appropriately when controlling a negative or a positive charge, which has a tendency to be implanted due to a thermodynamic unstable reaction according to an excess or a deficiency of oxygen supply and a growth temperature, at the time of forming a high-k metallic oxide film. That is, an insulation film having a high quality produced by the present invention improves conductivity, by reducing a tunneling current and an interface state density and raising a carrier mobility in a channel of a device. At the same time, a noise characteristic (1/f) of the device can be decreased to 1/10 times or less by lowering a trap-detrap of a carrier at an interface.

According to the present invention, a high quality oxide film having a thickness of 1 to 2 nm could be grown. The quantum well layer could be maintained with a superior characteristic when the oxide film has the thickness as mentioned above. In addition, a high quality low temperature oxide film, which may be useful for manufacturing the CMOS device having nano scale, can be formed at a relatively low temperature and low pressure, by irradiating a light having a short wavelength such as UV to a reaction gas to form a large quantity of radical and feeding the resultant radicals into a growth chamber to control components of radicals and an energy distribution.

Meanwhile, a low frequency noise (1/f) resulting from unstable bonding of silicon (Si), which generally exists in a gate oxide film within 1 nm from a channel, deteriorates a noise performance in a high-speed circuit of the CMOS device. According to a radical assisted oxidation apparatus of the present invention, a low frequency noise characteristic can be improved remarkably by reducing a defect density at an interface. In other words, a transistor having excellent noise and conduction characteristics can be manufactured, by controlling an energy distribution and a radical component having high reactivity at a low temperature and an ultra clean state, and growing an oxide film in which a defect is minimized.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

The present application contains subject matter related to korean patent application no. 2003-86660, filed in the Korean Patent Office on Dec. 2, 2003, the entire contents of which being incorporated herein by reference.

1. A radical assisted oxidation apparatus, comprising:
a gas supply system for supplying a plurality of reaction gases;
a radical source for generating a radical by decomposing the reaction gas supplied from the gas supply system;
a growth chamber for receiving the radical and the reaction gas, and having a plurality of lamps for heat treatment;
a load-lock chamber for transferring a wafer to the growth chamber; and
a vacuum system for making an interior of the growth chamber vacuum state and exhausting the reaction gas.

2. The radical assisted oxidation apparatus as claimed in claim 1, further comprising a control system for controlling operations of the gas supply system, the radical source, the growth chamber, the load-lock chamber, and the vacuum system.

3. The radical assisted oxidation apparatus as claimed in claim 1, wherein the plurality of lamps may be an IR lamp and an UV lamp.

4. The radical assisted oxidation apparatus as claimed in claim 1, a transfer arm for transferring the wafer is equipped in the load-lock chamber, and a thermocouple for heating the wafer is attached to the transfer arm.

5. The radical assisted oxidation apparatus as claimed in claim 1, a chamber for a surface treatment of a wafer is connected to the load-lock chamber through a cluster.

6. The radical assisted oxidation apparatus as claimed in claim 1, wherein the gas supply system comprising:
a plurality of gas supply lines into which the plurality of reaction gases are supplied, respectively; and
a flow regulator and a gas valve being equipped in each of the gas supply lines.

7. The radical assisted oxidation apparatus as claimed in claim 1, wherein the radical source comprising:
an outer cover in which a gas injection port and a gas exhaust port are formed;
a plurality of lamps being inserted into the outer cover and separated each other by a reflection film;
a plurality of electrodes for supplying a power supply to the plurality of lamps, respectively; and
gas lines of which edge portions at both sides are connected to the gas injection port and the gas exhaust port, respectively, the gas lines having a shape of a coil and being equipped so that the reaction gas circulates around the lamp.

8. The radical assisted oxidation apparatus as claimed in claim 7, further comprising sensors for monitoring states of the reaction gas and the lamp.

9. The radical assisted oxidation apparatus as claimed in claim 1, wherein the vacuum system comprising:
a gas exhaust line being connected to an exhaust port;
a gas exhaust line being connected to a pumping system;
a chamber separation valve for connecting each of the gas exhaust lines to the growth chamber, and separating the gas exhaust lines from the growth chamber; and
a plurality of valves being equipped in each of the gas exhaust lines.

10. The radical assisted oxidation apparatus as claimed in claim 1, the reaction gas comprises O₂, N₂, Ar, N₂O, NO₂, NH₃, H₂, HfCl₄, ZrCl₄, and TMA (Al).
